(19) United States
(12) Patent Application Publication
(10) Pub. No.: US 2026/0113985 A1
(43) Pub. Date: Apr. 23, 2026

(54) STACKED DEVICE WITH FLOATING CHANNEL LAYER AND MANUFACTURING METHOD THEREOF

(71) Applicant: TAIWAN SEMICONDUCTOR MANUFACTURING COMPANY, LTD., Hsinchu (TW)

(72) Inventors: Cheng-Ting CHUNG, Hsinchu City (TW); Jin CAI, Hsinchu City (TW)

(73) Assignee: TAIWAN SEMICONDUCTOR MANUFACTURING COMPANY, LTD., Hsinchu (TW)

(21) Appl. No.: 18/922,143

(22) Filed: Oct. 21, 2024

(51) Int. Cl. H01L 29/423; H01L 21/8234; H01L 27/092; H01L 29/06; H01L 29/08; H01L 29/417; H01L 29/66; H01L 29/775; H01L 29/786

(52) U.S. Cl. CPC H10D 30/6735; H10D 30/014; H10D 30/43; H10D 30/6757; H10D 62/115; H10D 62/121; H10D 62/151; H10D 64/017; H10D 64/251; H10D 84/013; H10D 84/038; H10D 84/85

(57) ABSTRACT

A device includes a bottom transistor and a top transistor over the bottom transistor to form a complementary field effect transistor. The bottom transistor includes an active channel layer, a floating channel layer, a gate structure, a first source/drain epitaxial structure, and a second source/drain epitaxial structure. The floating channel layer is over the active channel layer. The gate structure wraps around the active channel layer and the floating channel layer. The first source/drain epitaxial structure and the second source/drain epitaxial structure are connected to the active channel layer and spaced apart from the floating channel layer.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an integrated circuit structure (or a semiconductor device) in accordance with some embodiments of the present disclosure.

FIGS. 2-12C illustrate perspective views and cross-sectional views of intermediate stages in the formation of an integrated circuit structure (or a semiconductor device) in accordance with some embodiments of the present disclosure.

FIGS. 13A and 13B are cross-sectional view of integrated circuit structure (or a semiconductor device) in accordance with some embodiments of the present disclosure.

FIGS. 14A and 14B are cross-sectional view of integrated circuit structure (or a semiconductor device) in accordance with some embodiments of the present disclosure.

FIGS. 15A and 15B are cross-sectional view of integrated circuit structure (or a semiconductor device) in accordance with some embodiments of the present disclosure.

FIGS. 16A-19B illustrate exemplary cross-sectional views of various stages for manufacturing an integrated circuit structure (or a semiconductor device) according to some other embodiments of the present disclosure.

FIGS. 20A and 20B are cross-sectional view of integrated circuit structure (or a semiconductor device) in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9). As used herein, the term “low-k” refers to a low dielectric constant. In the field of semiconductor device structures and manufacturing processes, low-k refers to a dielectric constant that is less than the dielectric constant of SiO₂ (e.g., less than 3.9). As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit structures and methods of forming the same. More particularly, some embodiments of the present disclosure are related to stacked GAA devices including different numbers of active channel layers in different GAA FETs. Therefore, the stacked devices are able to satisfy varying requirements (e.g., high speed and low power applications) in different chip blocks (e.g., high performance computing (HPC) devices, central processing unit (CPU) device, system on a chip (SoC) applications, etc.).

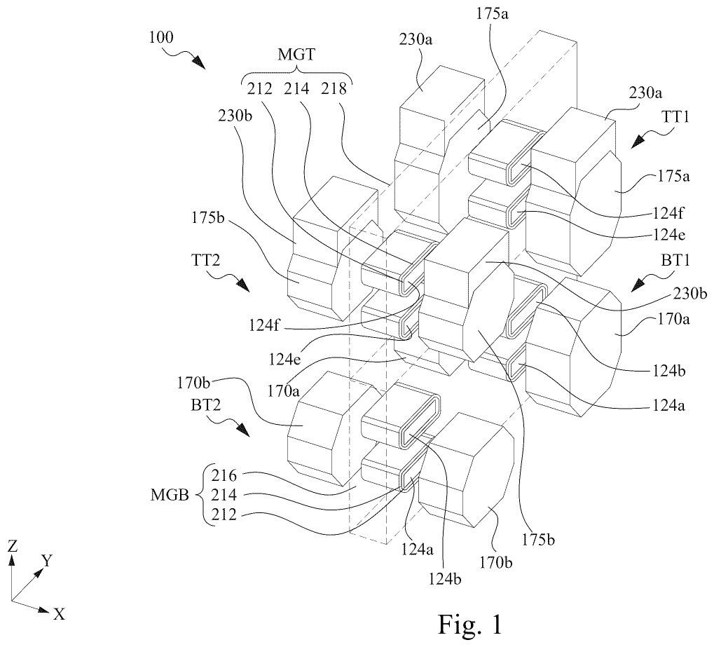

FIG. 1 is a perspective view of an integrated circuit structure (or a semiconductor device) 100 in accordance with some embodiments of the present disclosure. In the present disclosure, a semiconductor device 100 is provided, and its manufacturing method will be disclosed in the following discussion. In addition to the semiconductor device 100, FIG. 1 depicts X-axis, Y-axis, and Z-axis directions. In the semiconductor device 100, bottom transistors BT1 and BT2 are disposed over a substrate (not shown), and top transistors TT1 and TT2 are disposed vertically above the respective bottom transistors BT1 and BT2. In some embodiments, the bottom transistors BT1-BT2 and the top transistors TT1-TT2 each may be field effect transistor (FET) and may both include gate-all-around (GAA) configuration, and thus the bottom transistors BT1-BT2 and the top transistors TT1-TT2 can also be referred to as GAA FETs. The bottom transistor BT1 includes epitaxial layers 124a and 124b vertically stacked one above another, a gate structure MGB wrapping around each of the epitaxial layers 124a and 124b, and first source/drain epitaxial structures 170a on opposite ends of each of the epitaxial layers 124a and 124b. Similarly, the top transistor TT1 includes epitaxial layers 124e and 124f vertically stacked one above another, a gate structure MGT wrapping around each of the epitaxial layers 124e and 124f, and second source/drain epitaxial structures 175a on opposite ends of each of the epitaxial layers 124e and 124f.

On the other hand, the bottom transistor BT2 includes the epitaxial layers 124a and 124b vertically stacked one above another, the gate structure MGB wrapping around each of the epitaxial layers 124a and 124b, and first source/drain epitaxial structures 170b on opposite ends of the epitaxial layer 124a. Similarly, the top transistor TT2 includes the epitaxial layers 124e and 124f vertically stacked one above another, the gate structure MGT wrapping around each of the epitaxial layers 124e and 124f, and second source/drain epitaxial structures 175b on opposite ends of the epitaxial layer 124f.

The gate structure MGB may include an interfacial layer 212, a high-k gate dielectric layer 214, and a work function metal layer 216. Similarly, the gate structure MGT may include the interfacial layer 212, the high-k gate dielectric layer 214, and a work function metal layer 218. In some embodiments, each of the bottom transistors BT1 and BT2 has a first conductivity type (e.g., p-type) and each of the top transistors TT1 and TT2 has a second conductivity type (e.g., n-type) different from the first conductivity type. In some embodiments, the bottom transistors BT1 and BT2 can be referred to as P-FETs, and the top transistors TT1 and TT2 can be referred to as N-FETs.

The semiconductor device 100 further includes source/drain contacts 230a and 230b disposed over the respective second source/drain epitaxial structures 175a and 175b. In some embodiments, the source/drain contacts 230a and 230b are respectively in contact with top surfaces of the corresponding second source/drain epitaxial structures 175a and 175b.

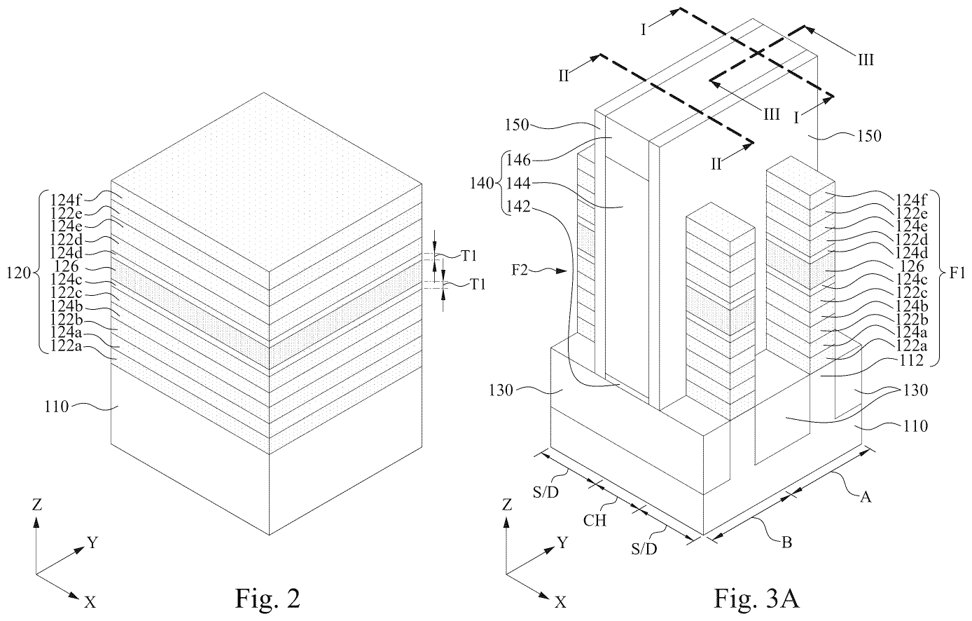

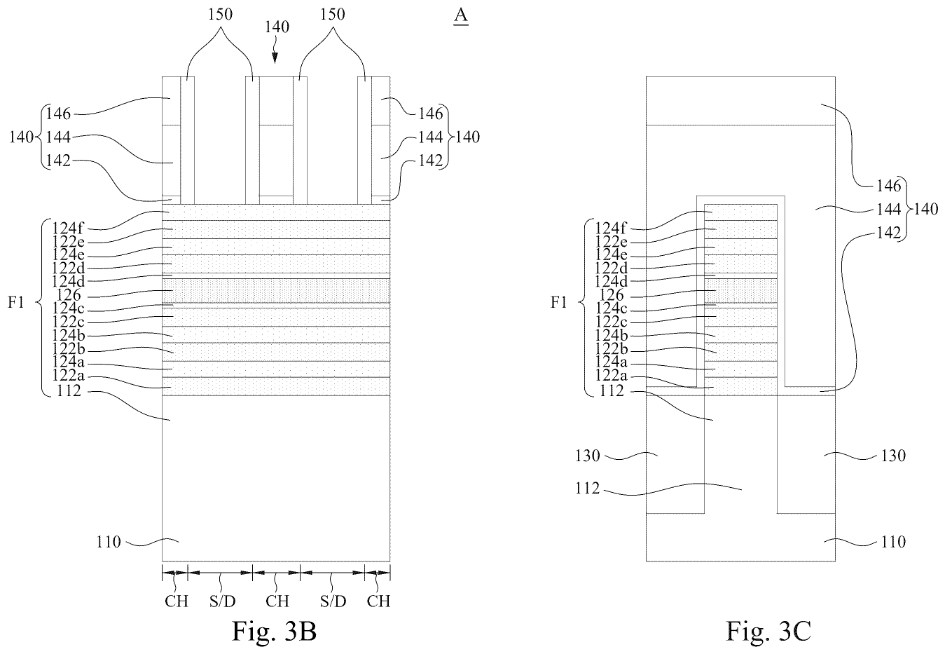

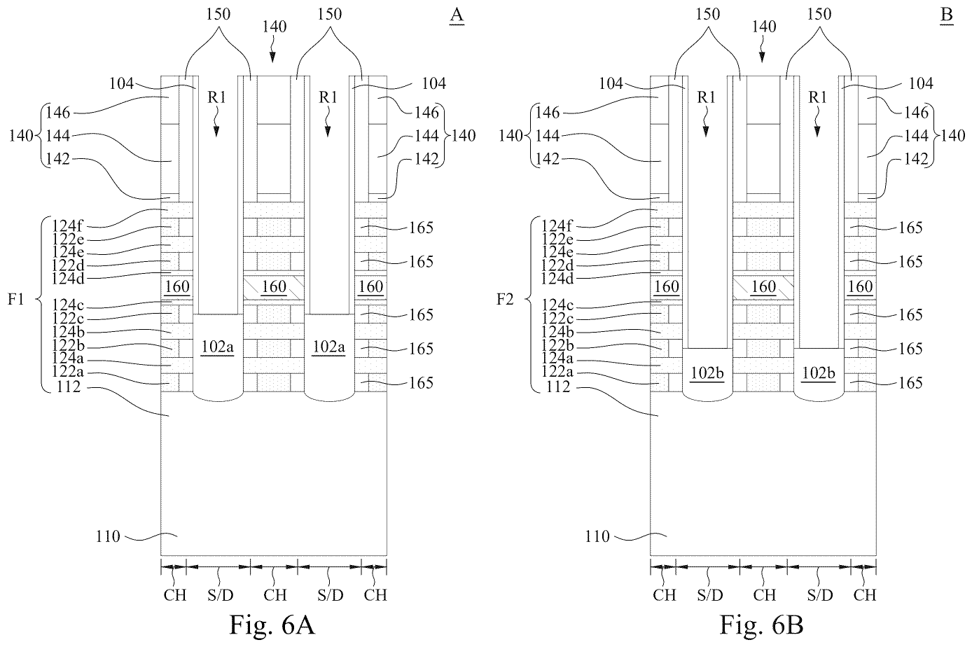

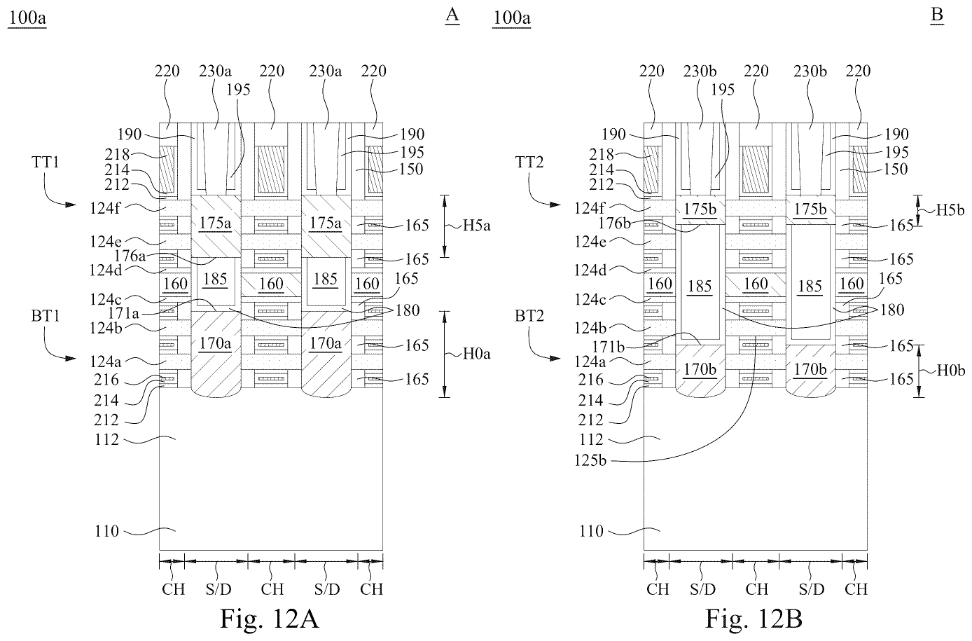

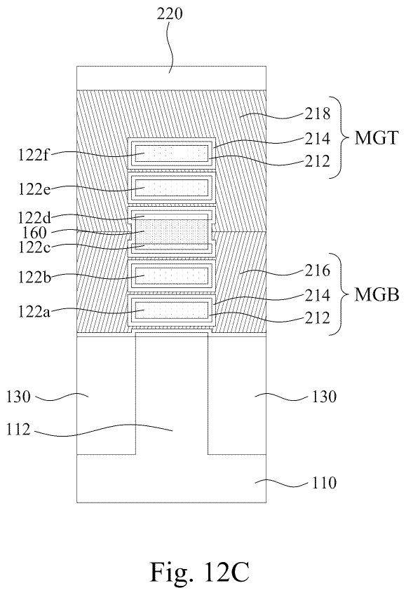

FIGS. 2-12C illustrate perspective views and cross-sectional views of intermediate stages in the formation of an integrated circuit structure (or a semiconductor device) 100a in accordance with some embodiments of the present disclosure. In some embodiments, the semiconductor device 100a in FIGS. 12A and 12B is a complementary FET (CFET) device. In addition to the semiconductor device 100a, FIGS. 2 and 3A depict X-axis, Y-axis, and Z-axis directions. FIGS. 3B, 4, 5, 6A, 7A, 8A, 9A, 10A, 11A, and 12A are cross-sectional views of some embodiments of the semiconductor device 100a at intermediate stages along a first cut (e.g., cut I-I in FIG. 3A). FIGS. 6B, 7B, 8B, 9B, 10B, 11B, and 12B are cross-sectional views of some embodiments of the semiconductor device 100a at intermediate stages along a second cut (e.g., cut II-II in FIG. 3A). FIGS. 3C, 11C, and 12C are cross-sectional views of some embodiments of the semiconductor device 100a at intermediate stages along a third cut (e.g., cut III-III in FIG. 3A). The formed devices include p-type transistors (such as p-type GAA FETs) and n-type transistors (such as n-type GAA FETs) in accordance with some exemplary embodiments. Throughout the various views and illustrative embodiments, like reference numbers are used to designate like elements. It is understood that additional operations can be provided before, during, and after the processes shown by FIGS. 2-12C, and some of the operations described below can be replaced or eliminated, for additional embodiments of the method. The order of the operations/processes may be interchangeable.

Referring to FIG. 2, an epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method.

The epitaxial stack 120 includes epitaxial layers 122a-122e of a first composition interposed by epitaxial layers 124a-124f of a second composition arranged in a stacking direction (Z-axis in this case). The epitaxial stack 120 further includes an epitaxial layer 126 between the epitaxial layer 124c and the epitaxial layer 124d of a third composition. The first, second, and third compositions are different. In some embodiments, the epitaxial layers 122a-122e and 126 are SiGe and the epitaxial layers 124a-124f are silicon (Si). Further, the germanium concentration of the epitaxial layer 126 is higher than the germanium concentration of the epitaxial layer 122a-122e. However, other embodiments are possible including those that provide for a first composition, a second composition, and a third composition having different etch selectivity.

The epitaxial layers 124a, 124b, 124e, and 124f or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the epitaxial layers 124a, 124b, 124e, and 124f to define a channel or channels of a device is further discussed below.

In FIG. 2, the epitaxial layers 124d, 124e, and 124f are disposed above the epitaxial layer 126 and the epitaxial layers 124a, 124b, and 124c. It is noted that three layers of the epitaxial layers 124a-124c and three layers of the epitaxial layers 124d-124f are arranged as illustrated in FIG. 2, which is for illustrative purposes only and not intended to be limiting beyond what is specifically recited in the claims. It can be appreciated that any number of epitaxial layers can be formed in the epitaxial stack 120; the number of layers depending on the desired number of channels regions for the transistor. In some embodiments, the number of each of the epitaxial layers 124a-124b and 124e-124f is between 2 and 10.

The epitaxial layers 122a-122c are interposed by the epitaxial layers 124a-124c, the epitaxial layers 122d-122e are interposed by the epitaxial layers 124d-124f, and the epitaxial layer 126 is between the epitaxial layers 124c and 124d. In some embodiments, each of the epitaxial layers 124c and 124d has a thickness T1 less than the thicknesses of the epitaxial layers 122a-122e and 124a, 124b, 124e, and 124f. In some embodiments, the epitaxial layers 124a, 124b, 124e, and 124f have substantially the same thickness.

As described in more detail below, the epitaxial layers 124a, 124b, 124e, and 124f may serve as channel region(s) for a subsequently-formed semiconductor device and the thickness is chosen based on device performance considerations. The epitaxial layers 122a-122e in channel regions(s) may eventually be removed and serve to define a vertical distance between adjacent channel region(s) for a subsequently-formed multi-gate device and the thickness is chosen based on device performance considerations. Accordingly, the epitaxial layers 122a-122e may also be referred to as sacrificial layers, and the epitaxial layers 124a, 124b, 124e, and 124f may also be referred to as channel layers.

By way of example, epitaxial growth of the layers of the epitaxial stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124a-124f include the same material as the substrate 110. In some embodiments, the epitaxial layers 122a-122e, 124a-124f, and 126 include a different material than the substrate 110. As stated above, in at least some examples, the epitaxial layers 122a-122e and 126 include an epitaxially grown silicon germanium (SiGe) layer and the epitaxial layers 124a-124f include an epitaxially grown silicon (Si) layer. Alternatively, in some embodiments, either of the epitaxial layers 122a-122e, 124a-124f, and 126 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the epitaxial layers 122a-122e, 124a-124f, and 126 may be chosen based on providing differing oxidation and/or etching selectivity properties.

Reference is made to FIGS. 3A-3C, where FIG. 3B is a cross-sectional view taken along line I-I of FIG. 3A, and FIG. 3C is a cross-sectional view taken along line III-III of FIG. 3A. It is noted that in the first cut (line I-I), three dummy gate structures 140 are illustrated to clearly show the detail of the semiconductor device 100a. Fin structures F1 and F2 extending from the substrate 110 are formed. A region A is defined to be a region including the fin structure F1 and the structures thereon, and a region B is defined to a region including the fin structure F2 and the structures thereon. In various embodiments, the fin structures F1 and F2 each includes a protruding portion 112 formed from the substrate 110 and portions of each of the epitaxial layers of the epitaxial stack including epitaxial layers 122a-122e, 124a-124f, and 126. The fin structures F1 and F2 may be fabricated using suitable processes including double-patterning or multi-patterning processes.

For example, a hard mask (HM) layer is formed over the epitaxial stack 120 prior to forming the fin structures F1 and F2. The fin structures F1 and F2 may subsequently be fabricated using suitable processes including photolithography and etch processes. The photolithography process may include forming a photoresist layer (not shown) over the HM layer, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process using light in EUV region, having a wavelength of, for example, about 1-200 nm. The patterned mask may then be used to protect regions of the substrate 110, and layers formed thereupon, while an etch process forms trenches in unprotected regions through the HM layer, through the epitaxial stack 120, and into the substrate 110, thereby leaving the fin structures F1 and F2. The trenches may be etched using a dry etch (e.g., reactive ion etching), a wet etch, and/or combination thereof. Numerous other embodiments of methods to form the fins on the substrate 110 may also be used including, for example, defining the fin region (e.g., by mask or isolation regions) and epitaxially growing the epitaxial stack 120 in the form of the fin structures F1 and F2.

Next, isolation structures 130 are formed to surround the fin structures F1 and F2. The isolation structures 130 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 130 may also include a dielectric material over the liner oxide, and the dielectric material may be formed using flowable chemical vapor deposition (FCVD), spin-on coating, or the like.

The isolation structures 130 are then planarized, such that the HM layer is removed, and the top surfaces of the fin structures F1 and F2 are exposed. Subsequently, the isolation structures 130 are recessed, so that the top portions of the fin structures F1 and F2 protrude higher than the top surfaces of the neighboring isolation structures 130. The etching may be performed using a dry etching process, wherein NH₃ and NF₃ are used as the etching gases. In accordance with alternative embodiments of the present disclosure, the recessing of the isolation structures 130 is performed using a wet etch process. The etching chemical may include diluted HF, for example.

At least one dummy gate structure 140 is formed over the substrate 110 and across the fin structures F1 and F2. The portions of the fin structures F1 and F2 underlying the dummy gate structure 140 may be referred to as channel regions CH. The dummy gate structure 140 may also define source/drain regions S/D of the fin structures F1 and F2, for example, the regions of the fin structures F1 and F2 adjacent and on opposite sides of the channel regions CH.

Dummy gate formation operation forms a dummy gate dielectric layer, a dummy gate electrode layer and a hard mask which may include multiple layers (e.g., a nitride layer and an oxide layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, a dummy gate structure 140 including a dummy gate dielectric layer 142, a dummy gate electrode layer 144 and a hard mask 146 (e.g., a nitride layer and an oxide layer) is formed.

After the formation of the dummy gate structure 140 is completed, gate spacers 150 are formed on opposite sidewalls of the dummy gate structure 140. For example, a spacer material layer is deposited on the substrate 110. The spacer material layer may be a conformal layer that is subsequently etched back to form gate sidewall spacers. In the illustrated embodiments, a spacer material layer is disposed conformally on top and sidewalls of the dummy gate structure 140. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer and a second spacer layer formed over the first spacer layer. By way of example, the spacer material layer may be formed by depositing a dielectric material over the dummy gate structure 140 using suitable deposition processes. An anisotropic etching process is then performed on the deposited spacer material layer to expose portions of the fin structures F1 and F2 not covered by the dummy gate structure 140 (e.g., over the source/drain regions S/D of the fin structures F1 and F2). Portions of the spacer material layer directly above the dummy gate structure 140 may be completely removed by this anisotropic etching process. Portions of the spacer material layer on sidewalls of the dummy gate structure 140 may remain, forming gate sidewall spacers, which are denoted as the gate spacers 150, for the sake of simplicity.

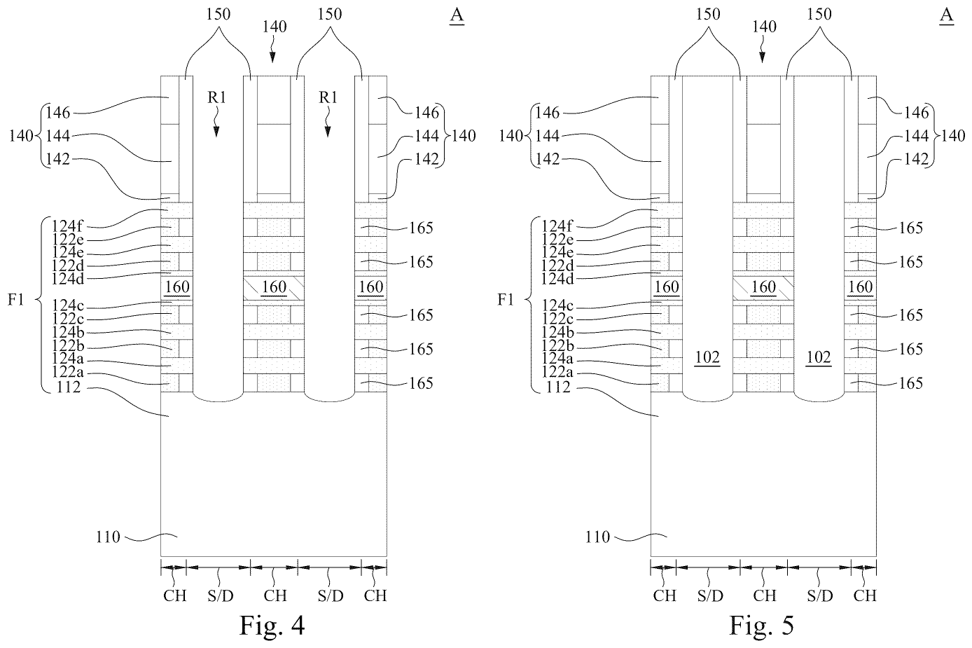

Next, as illustrated in FIG. 4, exposed portions of the fin structures F1 and F2 that extend laterally beyond the gate spacers 150 (e.g., in source/drain regions S/D of the fin structures F1 and F2) are etched by using, for example, an anisotropic etching process that uses the dummy gate structure 140 and the gate spacers 150 as an etch mask, resulting in recesses R1 into the fin structures F1 and F2. After the anisotropic etching, end surfaces of the epitaxial layers 122a-122e, 124a-124f, and 126 and respective outermost sidewalls of the gate spacers 150 are substantially coterminous, due to the anisotropic etching. In some embodiments, the anisotropic etching may be performed by a dry chemical etch with a plasma source and a reaction gas. The plasma source may be an inductively coupled plasma (ICP) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

The epitaxial layers 126 (see FIGS. 3A-3C) are removed, resulting in openings between the epitaxial layers 124c and 124d. Subsequently, middle dielectric isolators 160 are filled in the openings, respectively, such that the middle dielectric isolators 160 are between and in contact with the epitaxial layers 124c and 124d. For example, a dielectric material layer is formed to fill the opening. The dielectric material layer may be a low-k dielectric material, such as SiO₂, SiN, SiC, SiON, SiCN, or SiOCN, and may be formed by a suitable deposition method, such as ALD. In some embodiments, the dielectric material layer is intrinsic or un-doped with impurities. The dielectric material layer can be formed using CVD, including LPCVD and PECVD, PVD, ALD, or other suitable processes.

After the deposition of the dielectric material layer, an anisotropic etching process may be performed to remove the dielectric material layer outside the openings, such that portions of the deposited dielectric material layer that fill the openings are left. After the etching process, the remaining portions of the deposited spacer material in the openings are denoted as the middle dielectric isolators 160, for the sake of simplicity. The middle dielectric isolator 160 serves to isolate the epitaxial layers 124a-124b from the epitaxial layers 124e-124f.

The epitaxial layers 122a-122e are then laterally or horizontally recessed by using suitable etch techniques, resulting in lateral recesses each vertically between corresponding epitaxial layers 124a-124f. These operations may be performed by using selective etching processes. In some embodiments, the selective dry etching etches SiGe at a faster etch rate than it etches Si.

Subsequently, inner dielectric spacers 165 are filled in the recesses, respectively. For example, spacer material layers are formed and then trimmed to fill the recesses. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

Reference is made to FIG. 5. Dummy materials 102 are formed in the recesses R1 (see FIG. 4). In greater detail, the dummy materials 102 may be formed by, for example, depositing a dielectric material filling the recesses R1. In some embodiments, the dummy materials 102 may be made of SiOC, SiOₓ, the like, or other suitable material.

Reference is made to FIGS. 6A-6B. It is noted that in the first cut (line I-I) and the second cut (line II-II), three dummy gate structures 140 are illustrated to clearly show the detail of the integrated circuit structure 100a. The dummy materials 102 in FIG. 5 are then etched back to expose the gate spacers 150, the epitaxial layers 124f, 124e, 124d, and 124c, and the middle dielectric isolators 160. After the etching back process, the dummy materials still cover the epitaxial layers 124a and 124b, and the remaining portions of the deposited dummy materials in the recesses R1 in the region A are denoted as the dummy materials 102a, for the sake of simplicity.

Thereafter, a mask is formed over the substrate 110, such that the mask covers the structure in the region A and exposes the structure in the region B. Next, an additional etching back process is performed to lower the height of the dummy materials in the region B. Therefore, the sidewalls of the epitaxial layers 124b of the fin structure F2 are further exposed by the dummy materials. After the additional etching back process, the mask is removed, and the dummy materials in the region B still cover the epitaxial layers 124a but expose the epitaxial layers 124b. The remaining portions of the deposited dummy materials in the recesses R1 in the region B are denoted as the dummy materials 102b, for the sake of simplicity.

Afterwards, liners 104 are formed lining sidewalls of the upper portions of the recesses R1, so as to cover the sidewall surfaces of the epitaxial layers 124b-124f. The liners 104 may also cover the sidewalls of the gate spacers 150. In some embodiments, the liners 104 may be formed by, for example, depositing a liner layer blanket over the substrate, an anisotropic etching process is performed to remove horizontal portions of the liner layer, such that vertical portions of the liner layer remain on sidewalls of the epitaxial layers 124b-124f and the gate spacers 150. In some embodiments, the remaining vertical portions can be referred to as the liners 104. In some embodiments, the liners 104 may be made of SiN, metal oxide, or other suitable material.

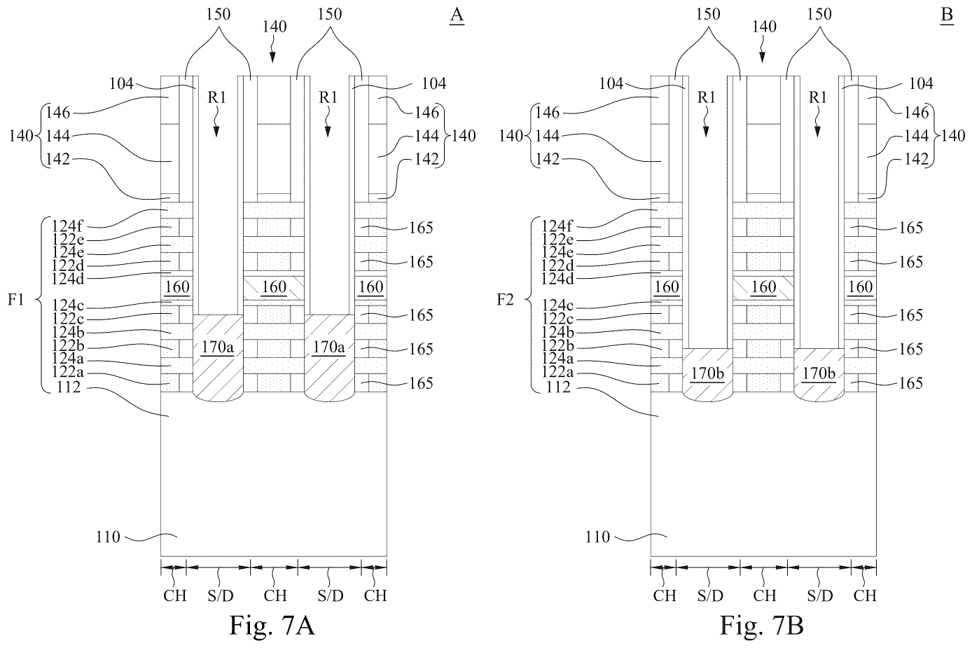

Reference is made to FIGS. 7A-7B. The dummy materials 102a and 102b (see FIGS. 6A and 6B) are removed by suitable etching process, so as to expose the sidewalls of the epitaxial layers 124a (and 124b in the region A). In some embodiments, the liners 104 may include a higher etching resistance to the etching process than the dummy materials 102a and 102b, and thus the liners 104 may remain after the dummy materials 102a and 102b are removed.

First source/drain epitaxial structures 170a and 170b are formed over the source/drain regions S/D. The first source/drain epitaxial structures 170a are on opposite sides and connected to the epitaxial layers 124a-124b and spaced apart from the epitaxial layers 124c-124f, and the first source/drain epitaxial structures 170b are on opposite sides and connected to the epitaxial layers 124a and spaced apart from the epitaxial layers 124b-124f. The first source/drain epitaxial structures 170a and 170b may be formed by performing an epitaxial growth process that provides an epitaxial material on the fin structures F1 and F2. During the epitaxial growth process, the liners 104 and the inner dielectric spacers 165 limit the first source/drain epitaxial structures 170a and 170b to the source/drain regions S/D. In some embodiments, the lattice constants of the first source/drain epitaxial structures 170a and 170b are different from the lattice constant of the epitaxial layers 124a (and 124b), so that the epitaxial layers 124a (and 124b) can be strained or stressed by the first source/drain epitaxial structures 170a and 170b to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the epitaxial layers 124a (and 124b).

In some embodiments, the first source/drain epitaxial structures 170a and 170b may include Ge, Si, GaAs, AlGaAs, SiGe, GaAsP, SiP, or other suitable material. The first source/drain epitaxial structures 170a and 170b may be in-situ doped during the epitaxial process by introducing doping species including: p-type dopants, such as boron or BF₂; n-type dopants, such as phosphorus or arsenic; and/or other suitable dopants including combinations thereof. If the first source/drain epitaxial structures 170a and 170b are not in-situ doped, an implantation process (i.e., a junction implant process) is performed to dope the first source/drain epitaxial structures 170a and 170b. In some exemplary embodiments, the first source/drain epitaxial structures 170a and 170b are in a p-type including SiGeB and/or GeSnB.

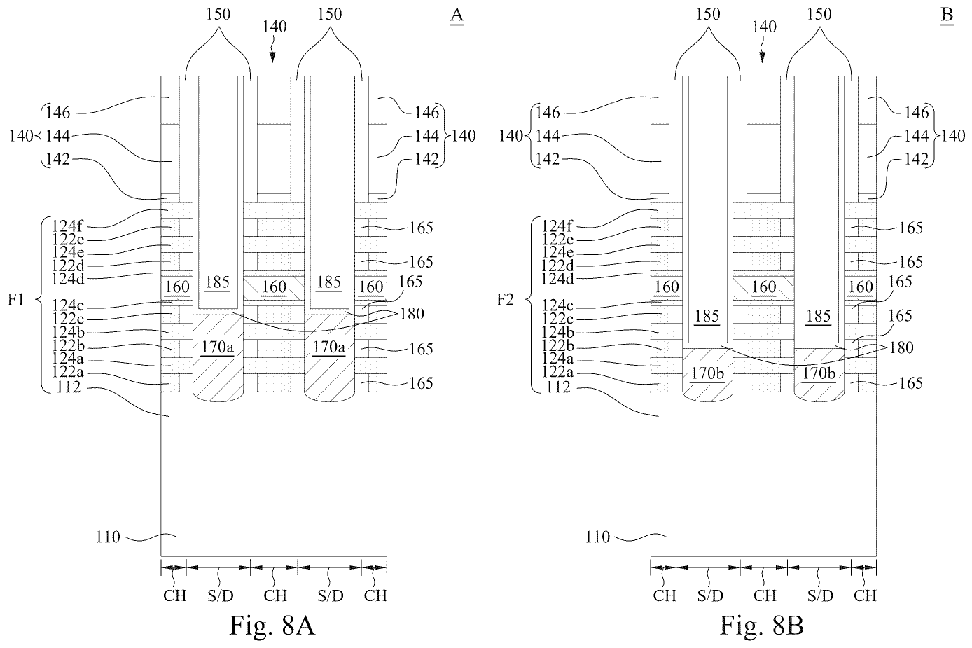

Reference is made to FIGS. 8A-8B. The liners 104 in FIGS. 7A-7B are removed. A first contact etch stop layer (CESL) 180 is then formed on the substrate 110 and covers the first source/drain epitaxial structures 170a and 170b. In some examples, the first CESL 180 includes a silicon nitride layer, silicon oxide layer, a silicon oxynitride layer, and/or other suitable materials. The first CESL 180 may be formed by plasma-enhanced chemical vapor deposition (PECVD) process and/or other suitable deposition or oxidation processes.

A first interlayer dielectric (ILD) layer 185 is then formed over the first CESL 180 and fills the recesses R1 (see FIGS. 7A and 7B). In some embodiments, the first ILD layer 185 includes materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the first CESL 180. The first ILD layer 185 may be deposited by a PECVD process or other suitable deposition technique. In some embodiments, after formation of the first ILD layer 185, the wafer may be subject to a high thermal budget process to anneal the first ILD layer 185.

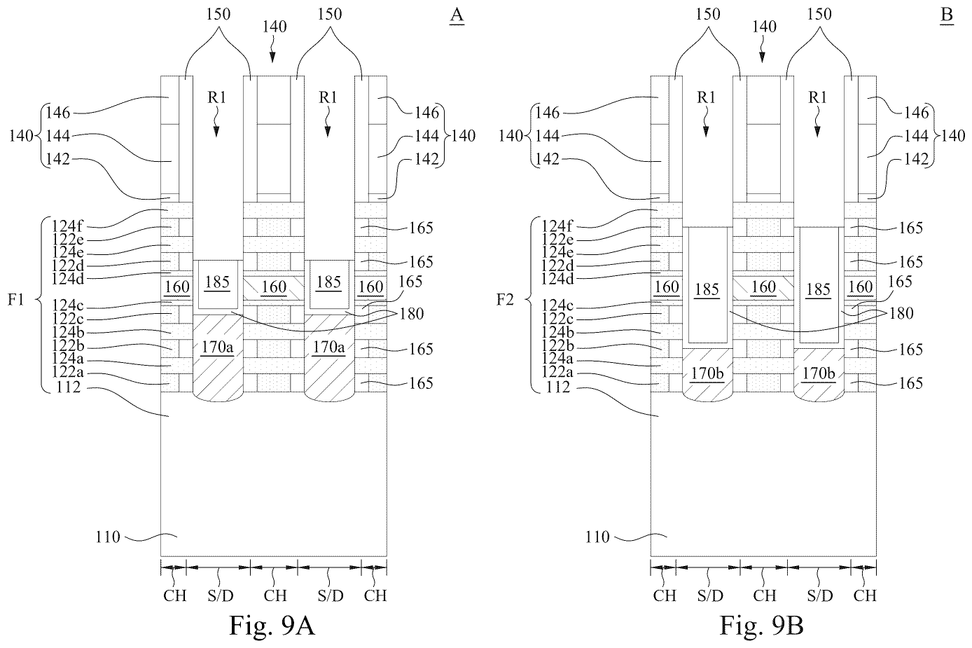

Reference is made to FIGS. 9A-9B. After the deposition of the first CESL 180 and the first ILD layer 185, the first CESL 180 and the first ILD layer 185 are then recessed to expose sidewalls of the epitaxial layers 124f as shown in FIG. 9B. Thereafter, another mask is formed over the substrate 110, such that the mask covers the region B but exposes the region A. Next, an additional recess (or etch) process is performed to lower the height of the first CESL 180 and the first ILD layer 185 in the region A. Therefore, the sidewalls of the epitaxial layers 124e of the fin structure F1 are further exposed by the first CESL 180 and the first ILD layer 185. On the other hand, as shown in FIG. 9B, the sidewalls of the epitaxial layers 124e of the fin structure F2 are still covered by the first CESL 180 and the first ILD layer 185. After the additional recess (or etch) process is performed, the mask covering the region B is removed.

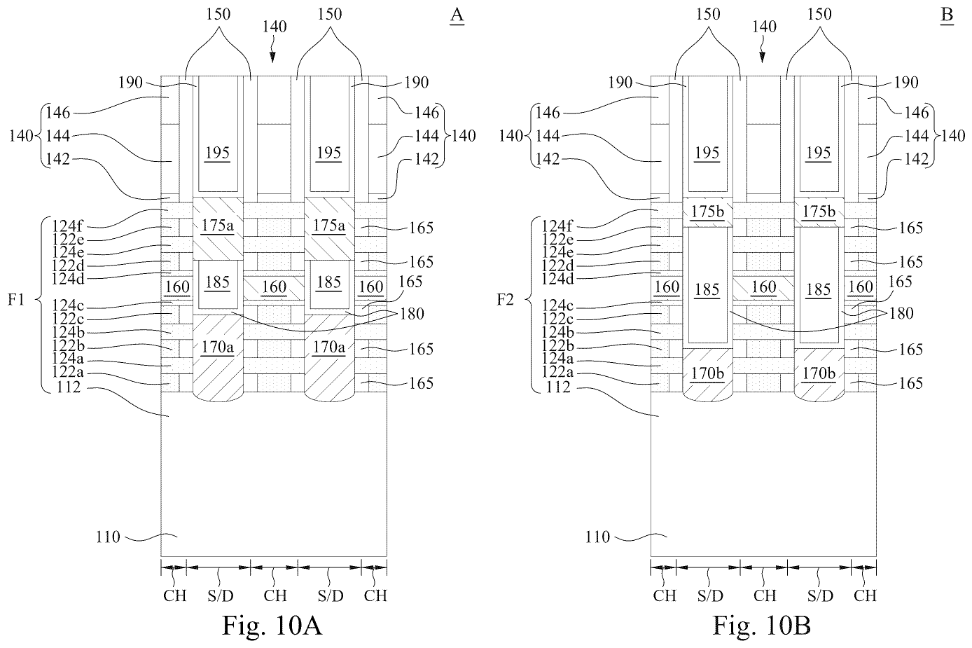

Reference is made to FIGS. 10A-10B. Second source/drain epitaxial structures 175a and 175b are formed over the source/drain regions S/D of the fin structures F1 and F2 and spaced apart from the first source/drain epitaxial structures 170a and 170b, respectively. The second source/drain epitaxial structures 175a are on opposite sides and connected to the epitaxial layers 124f and 124e, and the second source/drain epitaxial structures 175b are on opposite sides and connected to the epitaxial layers 124f. The second source/drain epitaxial structures 175a and 175b may be formed by performing an epitaxial growth process that provides an epitaxial material on the fin structures F1 and F2. During the epitaxial growth process, the first CESL 180, the first ILD layer 185, the inner dielectric spacers 165, and the gate spacers 150 limit the second source/drain epitaxial structures 175a and 175b to the source/drain regions S/D. In some embodiments, the lattice constants of the second source/drain epitaxial structures 175a and 175b are different from the lattice constant of the epitaxial layers 124f (and 124e), so that the epitaxial layers 124f (and 124e) can be strained or stressed by the second source/drain epitaxial structures 175a and 175b to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the epitaxial layers 124f (and 124e).

In some embodiments, the second source/drain epitaxial structures 175a and 175b may include Ge, Si, GaAs, AlGaAs, SiGe, GaAsP, SiP, or other suitable material. The second source/drain epitaxial structures 175a and 175b may be in-situ doped during the epitaxial process by introducing doping species including: p-type dopants, such as boron or BF₂; n-type dopants, such as phosphorus or arsenic; and/or other suitable dopants including combinations thereof. If the second source/drain epitaxial structures 175a and 175b are not in-situ doped, an implantation process (i.e., a junction implant process) is performed to dope the second source/drain epitaxial structures 175a and 175b. In some exemplary embodiments, the second source/drain epitaxial structures 175a and 175b are in an n-type include SiP and/or SiC.

A second CESL 190 is then formed on the substrate 110 and covers the second source/drain epitaxial structures 175a and 175b. In some examples, the second CESL 190 includes a material similar to or the same as the first CESL 180. A second ILD layer 195 is then formed over the second CESL 190 and fills the recesses R1 (see FIGS. 9A and 9B). In some embodiments, the second ILD layer 195 includes materials similar to or the same as the first ILD layer 185.

In some examples, after depositing the second ILD layer 195, a planarization process may be performed to remove excessive materials of the second ILD layer 195. For example, a planarization process includes a chemical mechanical planarization (CMP) process which removes portions of the second ILD layer 195 and the second CESL 190 overlying the dummy gate structures 140 and planarizes a top surface of the semiconductor device 100a.

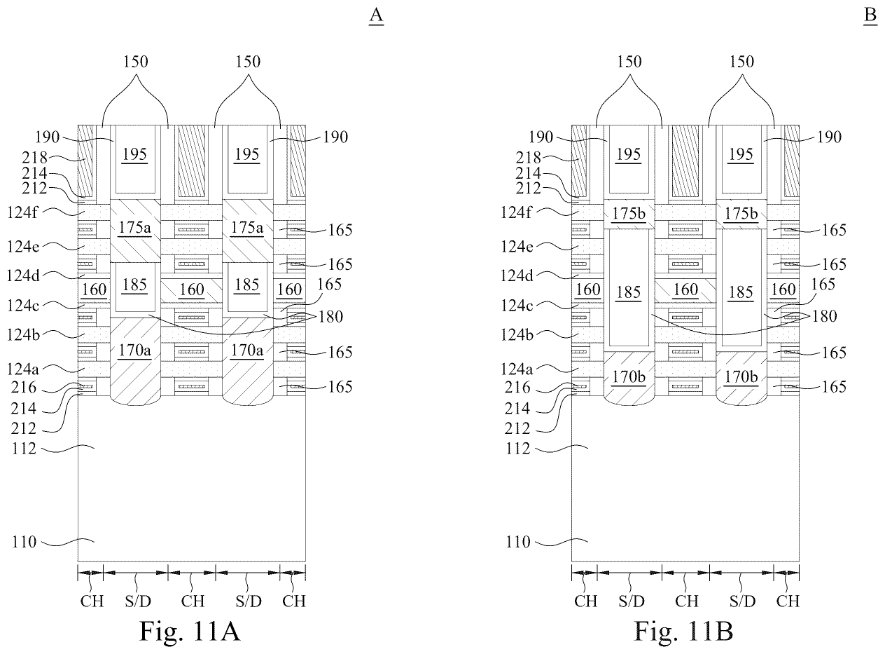

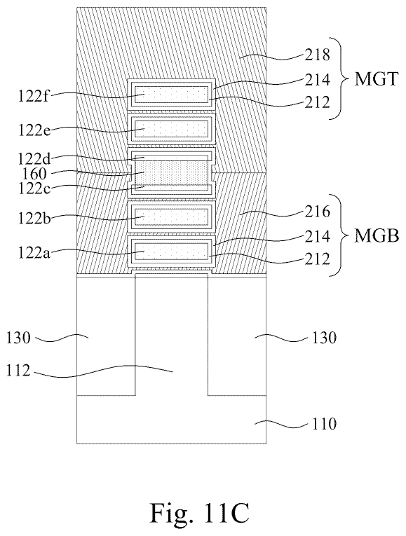

Reference is made to FIGS. 11A-11C. Thereafter, a gate replacement process is performed. Specifically, another CMP process is performed to remove the hard mask layers 146 (as shown in FIGS. 10A and 10B) and exposes the dummy gate electrode layer 144. Thereafter, the dummy gate electrode layer 144 and the dummy gate dielectric layer 142 are removed, and then the epitaxial layers (i.e., sacrificial layers) 122a-122e are removed. In some embodiments, the dummy gate electrode layer 144 is removed by using a selective etching process (e.g., selective dry etching, selective wet etching, or combinations thereof) that etches the materials in dummy gate electrode layer 144 at a faster etch rate than it etches other materials (e.g., the gate spacers 150 and/or the second ILD layer 195), thus resulting in gate trenches between the gate spacers 150, with the epitaxial layers 122a-122e exposed in the gate trenches. Subsequently, the epitaxial layers 122a-122e in the gate trenches are removed by using another selective etching process that etches the epitaxial layers 122a-122e at a faster etch rate than it etches the epitaxial layers 124a-124f, thus forming openings between neighboring epitaxial layers 124a-124f. In this way, the epitaxial layers 124a-124f become nanosheets suspended over the substrate 110. This operation is also called a channel release process. In some embodiments, the epitaxial layers 124a-124f can be interchangeably referred to as nanostructure (nanowires, nanoslabs and nanorings, nanosheet, etc., depending on their geometry). For example, in some other embodiments the epitaxial layers 124a-124f may be trimmed to have a substantial rounded shape (i.e., cylindrical) due to the selective etching process for completely removing the epitaxial layers 124a-124f. In that case, the resultant epitaxial layers 124a-124f can be called nanowires.

In some embodiments, the epitaxial layers 122a-122e are removed by using a selective dry etching process by using, for example, CF₄ as etching gases. In some embodiments, the epitaxial layers 122a-122e are SiGe and the epitaxial layers 124a-124f are silicon allowing for the selective removal of the epitaxial layers 122a-122e.

Interfacial layers 212 are then formed around the epitaxial layers 124a-124f. In some embodiments, the interfacial layer 212 may include a dielectric material such as silicon oxide (SiO₂), HfSiO, or silicon oxynitride (SiON). The interfacial layers 212 may be formed by chemical oxidation, thermal oxidation, atomic layer deposition (ALD), chemical vapor deposition (CVD), and/or other suitable method. In some embodiments, when the interfacial layers 212 are formed by oxidation, the interfacial layers 212 are grown on the surfaces of semiconductor materials, such as the epitaxial layers 124a-124f.

Thereafter, high-k gate dielectric layers 214 are formed to cover the interfacial layers 212. High-k gate dielectrics include dielectric materials having a high dielectric constant, for example, greater than that of thermal silicon oxide (˜3.9). The high-k gate dielectric layer 214 of the gate dielectric layer may include hafnium oxide (HfO₂). Alternatively, the high-k gate dielectric layer 214 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO2), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The high-k gate dielectric layers 214 may be formed by atomic layer deposition (ALD), chemical vapor deposition (CVD), and/or other suitable method.

Next, a work function metal layer 216 is deposited in the gate trenches and fills the gate trenches. The work function metal layer 216 may include work function metals to provide a suitable work function for (metal) gate structures MGB. For a p-type FET, the work function metal layer 216 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. The work function metal layer 216 may be formed by atomic layer deposition (ALD), chemical vapor deposition (CVD), and/or other suitable method. Subsequently, one or more CMP processes are performed to remove excessive gate materials.

After the formation of the work function metal layer 216, the work function metal layer 216 is etched back by using an etching process, and the top portions of the high-k gate dielectric layers 214 are exposed. Subsequently, another work function metal layer 218 is deposited in the gate trenches and over the work function metal layer 216 and fill the gate trenches. For an n-type FET, the work function metal layer 218 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials.

Therefore, the interfacial layers 212, the high-k gate dielectric layers 214, and the work function metal layer 216 form a gate structure MGB, and the interfacial layers 212, the high-k gate dielectric layers 214, and the work function metal layer 218 form a (metal) gate structure MGT over the gate structure MGB.

Reference is made to FIGS. 12A-12C. After the formation of the gate structures MGB and MGT as shown in FIGS. 11A-11C, an etching back process is optionally performed to etch back the gate structure MGT, resulting in a recess over the etched-back gate structure MGT. In some embodiments, because the materials of the gate structures MGT have a different etch selectivity than the gate spacers 150, a selective etching process may be performed to etch back the gate structure MGT to lower the gate structure MGT. As a result, the top surface of the gate structure MGT may be at a lower level than the top surfaces of the gate spacers 150.

Subsequently, a dielectric cap layer is deposited over the substrate 110 until the recess is overfilled. The dielectric cap layer includes SiNₓ, AlₓO_{y}, AlON, SiOₓC_{y}, SiCₓN_{y}, boron nitride (BN), boron carbonitride (BNC), combinations thereof or the like, and is formed by a suitable deposition technique such as CVD, plasma-enhanced CVD (PECVD), ALD, remote plasma ALD (RPALD), plasma-enhanced ALD (PEALD), combinations thereof or the like. A CMP process is then performed to remove the cap layer outside the recess, leaving portions of the dielectric cap layer in the recess to serve as dielectric caps 220. The dielectric caps 220 are in direct contact with the gate structure MGT as shown in FIGS. 12A-12C.

Next, openings are formed in the second ILD layer 195. The opening exposes the second source/drain epitaxial structures 175a and 175b. Source/drain contacts 230a and 230b are then respectively formed in the openings. In some embodiments, prior to the formation of the source/drain contacts 230a and 230b, metal alloy layers are formed in the openings and on the exposed portions of the second source/drain epitaxial structures 175a and 175b. Each of the source/drain contacts 230a is connected to the corresponding second source/drain epitaxial structure 175a, and each of the source/drain contacts 230b is connected to the corresponding second source/drain epitaxial structure 175b. Formation of the source/drain contacts 230a and 230b includes depositing one or more conductive (e.g., metal) materials overfilling the openings and then performing a CMP process to remove excessive metal materials outside the openings.

As such, the semiconductor device 100a is formed. As shown in FIGS. 12A-12C, the semiconductor device 100a includes bottom (nanostructure) transistors BT1 and BT2, and top (nanostructure) transistors TT1 and TT2. The top transistor TT1 and the bottom transistor BT1 form a CFET, and the top transistor TT2 and the bottom transistor BT2 form another CFET. The bottom transistors BT1 and BT2 are over the substrate 110, the top transistor TT1 is directly over the bottom transistor BT1, and the top transistor TT2 is directly over the bottom transistor BT2. The bottom transistor BT1 includes the channel layers 124a and 124b, the first source/drain epitaxial structures 170a on opposite sides of the channel layers 124a-124b and connected to the channel layers 124a-124b, and the gate structure MGB wrapping around the channel layers 124a-124b. The top transistor TT1 includes the channel layers 124e and 124f, the second source/drain epitaxial structures 175a on opposite sides of the channel layers 124e-124f and connected to the channel layers 124e-124f, and the gate structure MGT wrapping around the channel layers 124e-124f. The bottom transistor BT2 includes the channel layers 124a, the first source/drain epitaxial structures 170b on opposite sides of the channel layers 124a and connected to the channel layers 124a, and the gate structure MGB wrapping around the channel layers 124a-124b. The top transistor TT1 includes the channel layers 124f, the second source/drain epitaxial structures 175a on opposite sides of the channel layers 124f and connected to the channel layers 124f, and the gate structure MGT wrapping around the channel layers 124e-124f. The channel layers 124a are substantially level with each other, and the channel layers 124b are substantially level with each other. The channel layers 124e are substantially level with each other, and the channel layers 124f are substantially level with each other. The bottom transistors BT1 and BT2 are P-type transistors, and the top transistors TT1 and TT2 are N-type transistors, or vice versa.

It is noted that in FIG. 12B, although the gate structure MGB wraps around the channel layer 124b (for example, the gate structure MGB is in contact with a top surface, a bottom surface, and sidewalls of the channel layer 124b), the channel layers 124b are not connected to the first source/drain epitaxial structures 170b. Therefore, for the bottom transistor BT2, the channel layer 124a is an active channel layer, and the channel layer 124b is a floating (or dummy) channel layer. Similarly, although the gate structure MGT wraps around the channel layer 124e (for example, the gate structure MGT is in contact with a top surface, a bottom surface, and sidewalls of the channel layer 124e), the channel layers 124e are not connected to the second source/drain epitaxial structures 175b. Therefore, for the top transistor TT2, the channel layer 124f is an active channel layer, and the channel layer 124e is a floating (or dummy) channel layer.

For the semiconductor device 100a, the transistors TT1 and BT1 each have active channel layers more than the active channel layers of the transistors TT2 and BT2. Therefore, the semiconductor device 100a provides different requirements with different transistors. For example, the transistors TT1 and BT1 may be used for achieving high operation speed in a specific integrated circuit, while the transistors TT2 and BT2 may suffice for, i.e., SoC application due to low power benefit. With such configuration, both high operation speed and low power applications can be satisfied in the semiconductor device 100a.

In FIGS. 12A and 12B, a size of each of the first source/drain epitaxial structures 170a is larger than a size of each of the first source/drain epitaxial structures 170b. For example, a height H0a of the first source/drain epitaxial structures 170a is greater than a height H0b of the first source/drain epitaxial structures 170b. A top surface 171a of the first source/drain epitaxial structures 170a is higher than a top surface 171b of the first source/drain epitaxial structures 170b. In FIG. 12A, the first CESL 180 between the top transistor TT1 and the bottom transistor BT1 is spaced apart from the channel layers 124b, while in FIG. 12B, the first CESL 180 between the top transistor TT2 and the bottom transistor BT2 is in contact with the channel layers 124b and the top surface 171b of the first source/drain epitaxial structures 170b. Further, the top surface 171b of the first source/drain epitaxial structures 170b is lower than bottom surfaces 125b of the epitaxial layers 124b.

A size of each of the second source/drain epitaxial structures 175a is larger than a size of each of the second source/drain epitaxial structures 175b. For example, a height H5a of the second source/drain epitaxial structures 175a is greater than a height H5b of the second source/drain epitaxial structures 175b. A bottom surface 176a of the second source/drain epitaxial structures 175a is lower than a bottom surface 176b of the second source/drain epitaxial structures 175b. Further, the bottom surface 176b of the second source/drain epitaxial structures 175b is higher than a position of the epitaxial layers 124e. In FIG. 12A, the first CESL 180 is spaced apart from the channel layers 124e, while in FIG. 12B, the first CESL 180 is in contact with the channel layers 124e.

The semiconductor device 100a further includes the middle dielectric isolators 160 between the channel layers 124a and 124f, i.e., between the top transistors TT1-TT2 and the bottom transistors BT1-BT2. Further, the middle dielectric isolators 160 are directly above the corresponding epitaxial layers 124a-124c and directly below the corresponding epitaxial layers 124d-124f. An interface between the gate structures MGT and MGB may be level with the middle dielectric isolators 160 as shown in FIG. 12C. In some embodiments, the semiconductor device 100a further includes the epitaxial layers 124c and 124d in contact with the middle dielectric isolators 160. The epitaxial layers 124c are directly over the corresponding epitaxial layers 124a-124b, and the epitaxial layers 124d are directly below the corresponding epitaxial layers 124e-124f. On contrary, the epitaxial layers 124b are separated from the middle dielectric isolators 160 by the gate structures MGB, i.e., a portion of the gate structure MGB is directly between the epitaxial layers 124b and 124c. The epitaxial layers 124e are separated from the middle dielectric isolators 160 by the gate structures MGT, i.e., a portion of the gate structure MGT is directly between the epitaxial layers 124d and 124e. Further, the epitaxial layers 124c and 124d are thinner than the epitaxial layers 124a, 124b, 124d, and 124e.

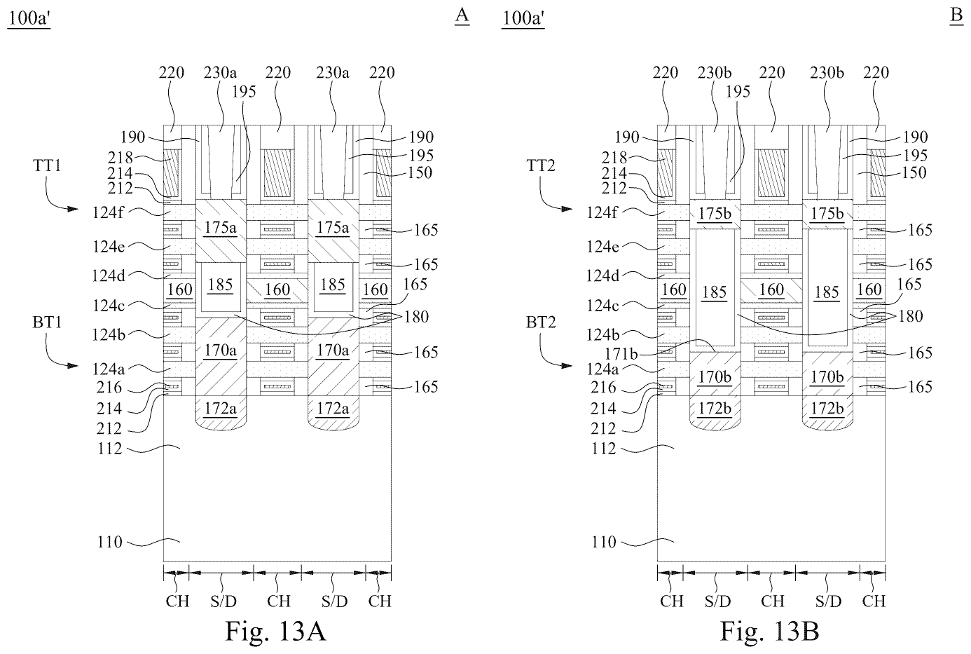

FIGS. 13A and 13B are cross-sectional view of integrated circuit structure (or a semiconductor device) 100a′ in accordance with some embodiments of the present disclosure. The difference between the semiconductor device 100a′ in FIGS. 13A and 13B and the semiconductor device 100a in FIGS. 12A and 12B pertains to bottom source/drain epitaxial structures 172a and 172b. In some embodiments as shown in FIGS. 13A and 13B, prior to forming the dummy materials 102 (see FIG. 5), bottom source/drain epitaxial structures 172a and 172b may be grown in the recesses R1. The semiconductor materials include a single element semiconductor material, such as germanium (Ge) or silicon (Si), compound semiconductor materials, such as gallium arsenide (GaAs) or aluminum gallium arsenide (AlGaAs), or a semiconductor alloy, such as silicon germanium (SiGe) or gallium arsenide phosphide (GaAsP). The bottom source/drain epitaxial structures 172a and 172b have suitable crystallographic orientations (e.g., a (100), (110), or (111) crystallographic orientation). The epitaxial processes include CVD deposition techniques (e.g., vapor-phase epitaxy (VPE) and/or ultra-high vacuum CVD (UHV-CVD)), molecular beam epitaxy, and/or other suitable processes. In some embodiments, the bottom source/drain epitaxial structures 172a and 172b are intrinsic. That is, the bottom source/drain epitaxial structures 172a and 172b are undoped. The undoped bottom source/drain epitaxial structures 172a and 172b are benefit for reducing current leakage from the first source/drain epitaxial structures 170a and 170b to the substrate 110. Other relevant structural and manufacturing details of the semiconductor device 100a′ are substantially the same or similar to the semiconductor device 100a of FIGS. 12A-12C, and, therefore, a description in this regard will not be repeated hereinafter.

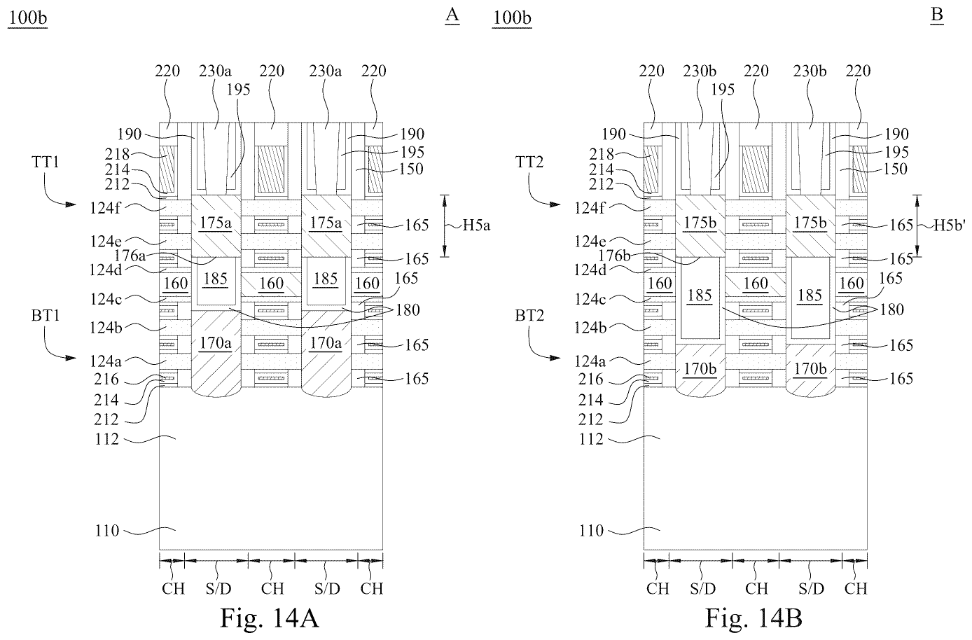

FIGS. 14A and 14B are cross-sectional view of integrated circuit structure (or a semiconductor device) 100b in accordance with some embodiments of the present disclosure. The difference between the semiconductor device 100b in FIGS. 14A and 14B and the semiconductor device 100a in FIGS. 12A and 12B pertains to the configuration of the second source/drain epitaxial structures 175b of the top transistor TT2. In FIGS. 14A and 14B, the top transistors TT1 and TT2 have substantially the same configuration. That is, a size of each of the second source/drain epitaxial structures 175a is substantially the same as a size of each of the second source/drain epitaxial structures 175b. For example, a height H5a of the second source/drain epitaxial structures 175a is substantially the same as a height H5b′ of the second source/drain epitaxial structures 175b. A bottom surface 176a of the second source/drain epitaxial structures 175a is substantially level with a bottom surface 176b of the second source/drain epitaxial structures 175b. In FIGS. 14A and 14B, the first CESL 180 is spaced apart from the channel layers 124e. Further, the size of the second source/drain epitaxial structures 175b is larger than the size of the first source/drain epitaxial structures 170b. With such configuration, the CFET in FIG. 14B may be applied to SRAM circuits, which may include 2-sheets NFET and 1-sheet PFET. However, the claimed scope is not limited to the SRAM applications. Other relevant structural and manufacturing details of the semiconductor device 100b are substantially the same or similar to the semiconductor device 100a of FIGS. 12A-12C, and, therefore, a description in this regard will not be repeated hereinafter.

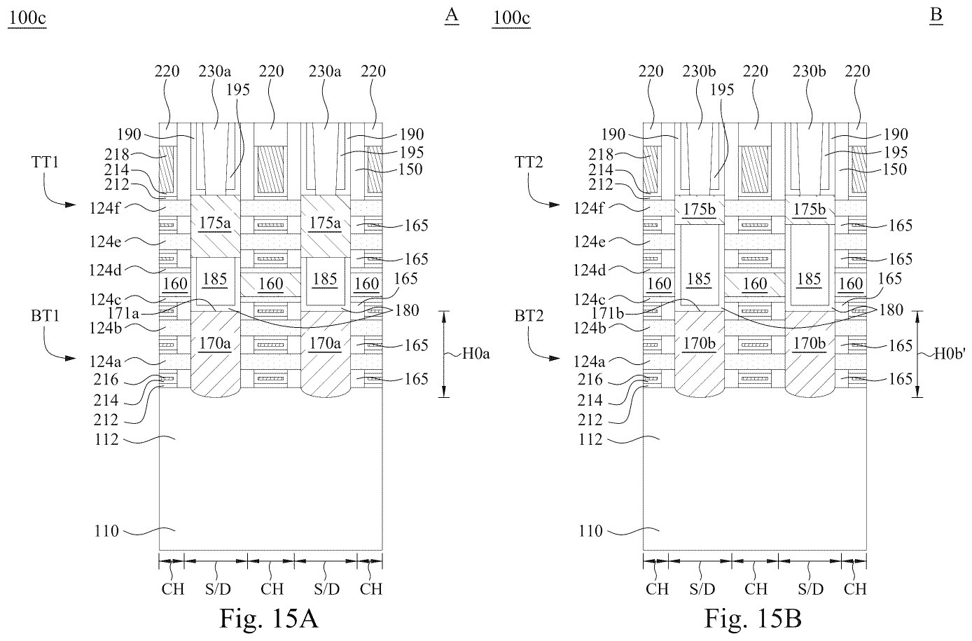

FIGS. 15A and 15B are cross-sectional view of integrated circuit structure (or a semiconductor device) 100c in accordance with some embodiments of the present disclosure. The difference between the semiconductor device 100c in FIGS. 15A and 15B and the semiconductor device 100a in FIGS. 12A and 12B pertains to the configuration of the first source/drain epitaxial structures 170b of the bottom transistor BT2. In FIGS. 15A and 15B, the bottom transistors BT1 and BT2 have substantially the same configuration. That is, a size of each of the first source/drain epitaxial structures 170a is substantially the same as a size of each of the first source/drain epitaxial structures 170b. For example, a height H0a of the first source/drain epitaxial structures 170a is substantially the same as a height H0b′ of the first source/drain epitaxial structures 170b. A top surface 171a of the first source/drain epitaxial structures 170a is substantially level with a top surface 171b of the first source/drain epitaxial structures 170b. In FIGS. 15A and 15B, the first CESL 180 is spaced apart from the channel layers 124b. Further, the size of the first source/drain epitaxial structures 170 is larger than the size of the second source/drain epitaxial structures 175b. With such configuration, the CFET in FIG. 15B may be applied to SRAM circuits, which may include 2-sheets PFET and 1-sheet NFET. However, the claimed scope is not limited to the SRAM applications. Other relevant structural and manufacturing details of the semiconductor device 100c are substantially the same or similar to the semiconductor device 100a of FIGS. 12A-12C, and, therefore, a description in this regard will not be repeated hereinafter.

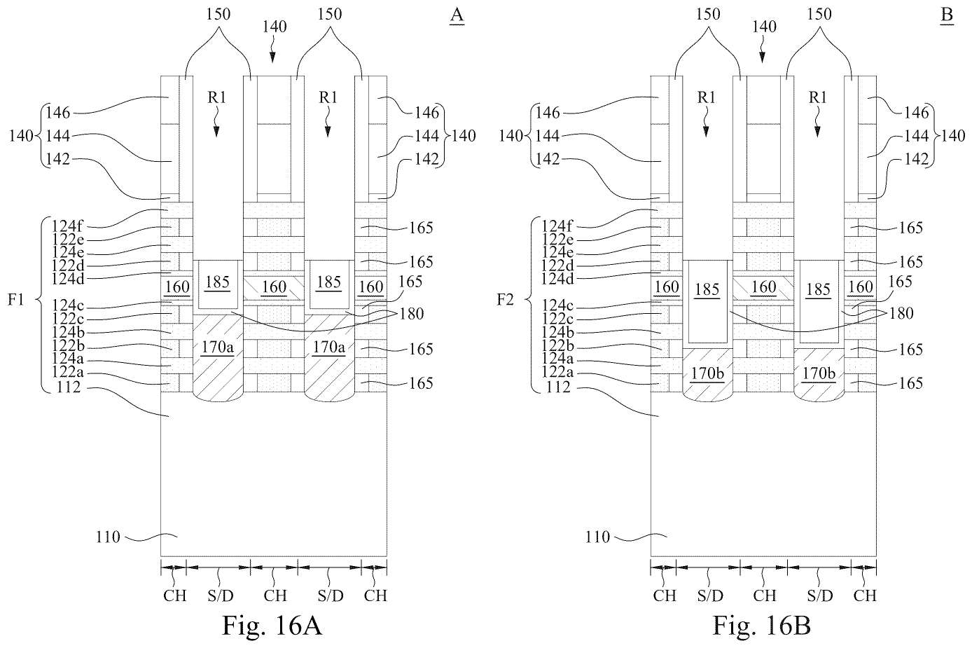

FIGS. 16A-19B illustrate exemplary cross-sectional views of various stages for manufacturing an integrated circuit structure (or a semiconductor device) 100d according to some other embodiments of the present disclosure. It is understood that additional operations can be provided before, during, and after processes shown by FIGS. 16A-19B, and some of the operations described below can be replaced or eliminated, for additional embodiments of the method. The order of the operations/processes may be interchangeable. The same or similar configurations, materials, processes and/or operation as described with FIGS. 2-12C may be employed in the following embodiments, and the detailed explanation may be omitted.

After the structure as shown in FIGS. 8A-8B is formed, the first CESL 180 and the first ILD layer 185 are then recessed to expose sidewalls of the epitaxial layers 124f and 124e as shown in FIGS. 16A and 16B. That is, the top surface of the first ILD layer 185 in the region A is substantially coplanar with the top surface of the first ILD layer 185 in the region B.

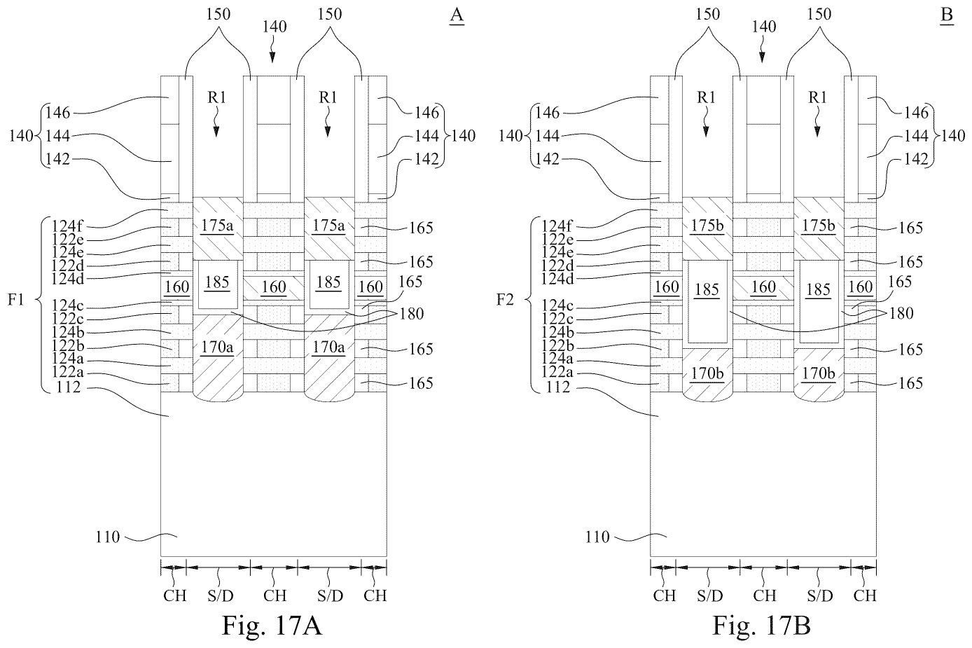

Reference is made to FIGS. 17A-17B. Second source/drain epitaxial structures 175a and 175b are formed over the source/drain regions S/D of the fin structures F1 and F2 and spaced apart from the first source/drain epitaxial structures 170a and 170b, respectively. The second source/drain epitaxial structures 175a and 175b are on opposite sides and connected to the epitaxial layers 124f and 124e. Process details about the formation of the second source/drain epitaxial structures 175a and 175b are discussed previously with respect to the second source/drain epitaxial structures 175a and 175b in FIGS. 10A-10B, and thus they are not repeated herein for the sake of brevity.

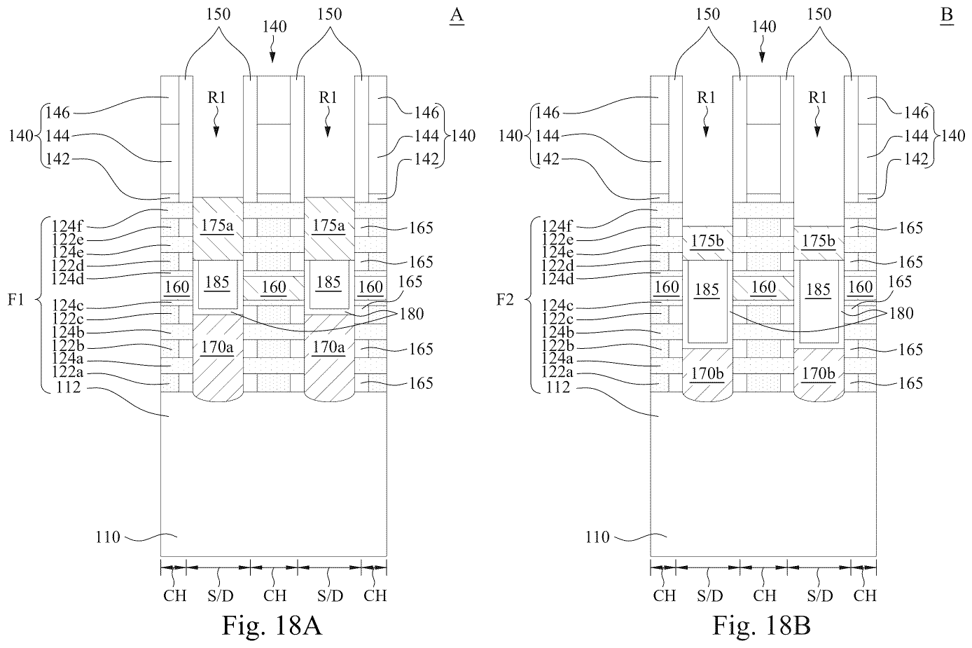

Reference is made to FIGS. 18A-18B. A mask is formed over the substrate 110 to cover the structure in the region A and exposes the structure in the region B. Next, an etching back process is performed to etch top portions of the second source/drain epitaxial structures 175b, such that top surfaces of the second source/drain epitaxial structures 175b are lowered, and the epitaxial layers 124f in the region B are exposed in the recesses R1. After the etching back process, the mask is removed.

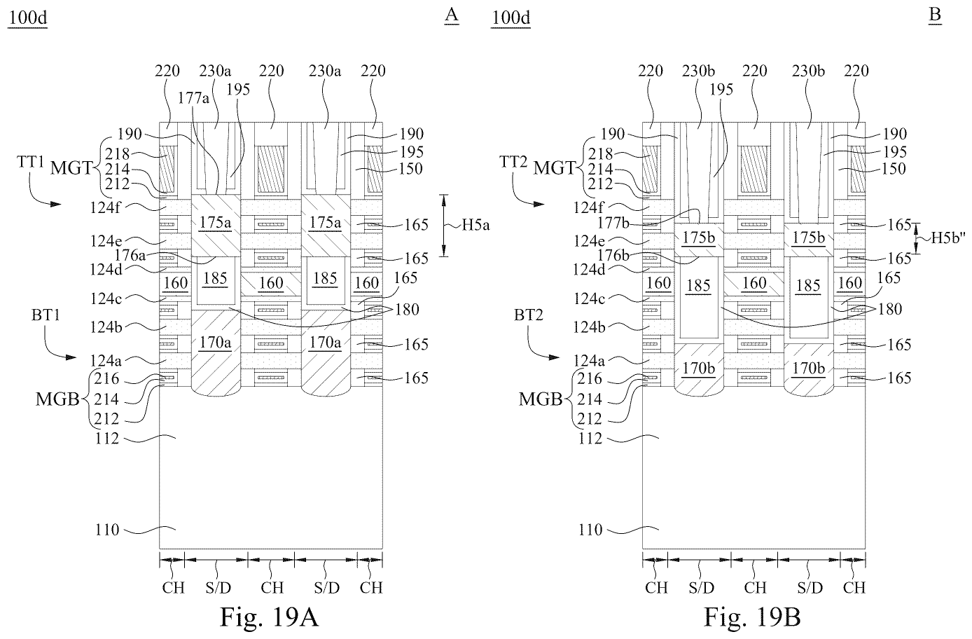

Reference is made to FIGS. 19A-19B. After the etching process in FIG. 18B is completed, the structure of FIGS. 18A-18B undergoes the processes similar to FIGS. 10A-12C. That is, the second CESL 190 and the second ILD 195 are formed in the recesses R1. The dummy gate structures 140 are then replaced with the gate structures MGT and MGB. The dielectric caps 220 are optionally formed over the gate structures MGT, and the source/drain contacts 230a and 230b are formed in the second ILD 195 to be connected to the second source/drain epitaxial structures 175a and 175b, respectively. As shown in FIGS. 19A-19B, the source/drain contacts 230b are deeper than the source/drain contacts 230a.

As such, the semiconductor device 100d is formed. As shown in FIGS. 19A-19B, the semiconductor device 100d includes bottom (nanostructure) transistors BT1 and BT2, and top (nanostructure) transistors TT1 and TT2. The difference between the semiconductor device 100d in FIGS. 19A and 19B and the semiconductor device 100a in FIGS. 12A and 12B pertains to the configuration of the second source/drain epitaxial structures 175b of the top transistor TT2. In FIGS. 19A and 19B, the second source/drain epitaxial structures 175a are connected to the epitaxial layers 124e and 124f, and the second source/drain epitaxial structures 175b are connected to the epitaxial layers 124e but spaced apart from the epitaxial layers 124f. Therefore, for the top transistor TT2, the channel layer 124e is an active channel layer, and the channel layer 124f is a floating (or dummy) channel layer. The second CESL 190 is in contact with the epitaxial layers 124f in the region B but spaced apart from the epitaxial layers 124f in the region A.

A size of the second source/drain epitaxial structures 175a is larger than a size of the second source/drain epitaxial structures 175b. For example, a height H5a of the second source/drain epitaxial structures 175a is greater than a height H5b″ of the second source/drain epitaxial structures 175b. A bottom surface 176a of the second source/drain epitaxial structures 175a is substantially coplanar with a bottom surface 176b of the second source/drain epitaxial structures 175b. However, a top surface 177a of the second source/drain epitaxial structures 175a is higher than a top surface 177b of the second source/drain epitaxial structures 175b. Further, the top surface 177b of the second source/drain epitaxial structures 175b is lower than a position of the epitaxial layers 124f. Other relevant structural and manufacturing details of the semiconductor device 100d are substantially the same or similar to the semiconductor device 100a of FIGS. 12A-12C, and, therefore, a description in this regard will not be repeated hereinafter.

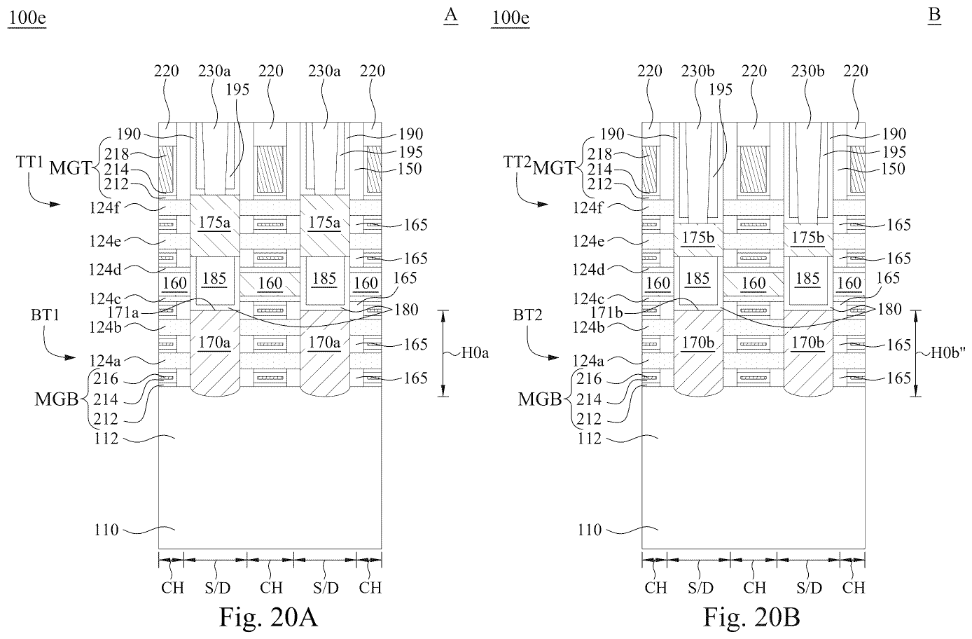

FIGS. 20A and 20B are cross-sectional view of integrated circuit structure (or a semiconductor device) 100e in accordance with some embodiments of the present disclosure. The difference between the integrated circuit structure 100e in FIGS. 20A and 20B and the integrated circuit structure 100d in FIGS. 19A and 19B pertains to the configuration of the first source/drain epitaxial structures 170b of the bottom transistor BT2. In FIGS. 20A and 20B, the bottom transistors BT1 and BT2 have substantially the same configuration. That is, a size of each of the first source/drain epitaxial structures 170a is substantially the same as a size of each of the first source/drain epitaxial structures 170b. For example, a height H0a of the first source/drain epitaxial structures 170a is substantially the same as a height H0b″ of the first source/drain epitaxial structures 170b. A top surface 171a of the first source/drain epitaxial structures 170a is substantially level with a top surface 171b of the first source/drain epitaxial structures 170b. In FIGS. 20A and 20B, the first CESL 180 is spaced apart from the channel layers 124b. Further, the size of the first source/drain epitaxial structures 170b is larger than the size of the second source/drain epitaxial structures 175b. With such configuration, the CFET in FIG. 20B may be applied to SRAM circuits, which may include 2-sheets PFET and 1-sheet NFET. However, the claimed scope is not limited to the SRAM applications. Other relevant structural and manufacturing details of the semiconductor device 100e are substantially the same or similar to the semiconductor device 100d of FIGS. 19A and 19B, and, therefore, a description in this regard will not be repeated hereinafter.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that different numbers of active channel layers can be applied to different GAA FETs in different chip blocks. As such, different requirements for different chip blocks can be satisfied. Further, the process flows for forming these semiconductor devices do not complex the original process flow, and they are easily added in varying processes flows.

According to some embodiments, a device includes a bottom transistor and a top transistor over the bottom transistor to form a complementary field effect transistor. The bottom transistor includes an active channel layer, a floating channel layer, a gate structure, a first source/drain epitaxial structure, and a second source/drain epitaxial structure. The floating channel layer is over the active channel layer. The gate structure wraps around the active channel layer and the floating channel layer. The first source/drain epitaxial structure and the second source/drain epitaxial structure are connected to the active channel layer and spaced apart from the floating channel layer.

According to some embodiments, a device includes a first bottom transistor, a second bottom transistor, a first top transistor, and a second top transistor. The first bottom transistor and the second bottom transistor are over a substrate. The first top transistor is directly over the first bottom transistor and includes a first epitaxial layer, a second epitaxial layer, a first gate structure, a first source/drain epitaxial structure, and a second source/drain epitaxial structure. The first epitaxial layer and the second epitaxial layer are over the first epitaxial layer. The first gate structure wrap around the first epitaxial layer and the second epitaxial layer. The first source/drain epitaxial structure and the second source/drain epitaxial structure are connected to the first epitaxial layer and the second epitaxial layer. The second top transistor is directly over the second bottom transistor and includes a third epitaxial layer, a fourth epitaxial layer, a second gate structure, a third source/drain epitaxial structure, and a fourth source/drain epitaxial structure. The third epitaxial layer and the fourth epitaxial layer are over the third epitaxial layer. The second gate structure wraps around the third epitaxial layer and the fourth epitaxial layer. The third source/drain epitaxial structure and the fourth source/drain epitaxial structure are connected to one of the third epitaxial layer and the fourth epitaxial layer but spaced apart from another one of the third epitaxial layer and the fourth epitaxial layer.

According to some embodiments, a method includes forming a fin structure over a substrate. The fin structure includes a first sacrificial layer, a first channel layer, a second sacrificial layer, a second channel layer, a third sacrificial layer, and a third channel layer arranged in a stacking direction. The first channel layer, the second channel layer, and the third channel layer have substantially the same thickness. A dummy gate structure is formed across the fin structure. Gate spacers are formed on opposite sides of the dummy gate structure. The fin structure are recessed by using the dummy gate structure and the gate spacers to be a mask to form a recess in the fin structure. Liners are formed in the recess and on sidewalls of the fin structure. The liners cover the second channel layer, and the third channel layer but expose the first channel layer. First source/drain epitaxial layers are formed on opposite sides of the first channel layer and spaced apart from the second channel layer and the third channel layer. The liners are removed. Second source/drain epitaxial layers are formed on opposite sides of the third channel layer and spaced apart from the first channel layer and the second channel layer. The dummy gate structure, the first sacrificial layer, the second sacrificial layer, and the third sacrificial layer are replaced with a metal gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a bottom transistor comprising:
an active channel layer and a floating channel layer over the active channel layer;
a gate structure wrapping around the active channel layer and the floating channel layer; and
a first source/drain epitaxial structure and a second source/drain epitaxial structure connected to the active channel layer and spaced apart from the floating channel layer; and
a top transistor over the bottom transistor to form a complementary field effect transistor.

2. The device of claim 1, further comprising a contact etch stop layer (CESL) between the bottom transistor and the top transistor, wherein the CESL is in contact with the floating channel layer and a top surface of the first source/drain epitaxial structure.

3. The device of claim 1, wherein a top surface of the first source/drain epitaxial structure is lower than a bottom surface of the floating channel layer.

4. The device of claim 1, further comprising a middle dielectric isolator between the top transistor and the bottom transistor, wherein the middle dielectric isolator is directly over the floating channel layer.

5. The device of claim 4, further comprising an epitaxial layer directly over the floating channel layer and in contact with the middle dielectric isolator.

6. The device of claim 5, wherein a portion of the gate structure is directly between the epitaxial layer and the floating channel layer.

7. The device of claim 5, wherein the epitaxial layer is thinner than the floating channel layer.

8. A device comprising:
a first bottom transistor and a second bottom transistor over a substrate;
a first top transistor directly over the first bottom transistor and comprising:
a first epitaxial layer and a second epitaxial layer over the first epitaxial layer;
a first gate structure wrapping around the first epitaxial layer and the second epitaxial layer; and
a first source/drain epitaxial structure and a second source/drain epitaxial structure connected to the first epitaxial layer and the second epitaxial layer; and
a second top transistor directly over the second bottom transistor and comprising:
a third epitaxial layer and a fourth epitaxial layer over the third epitaxial layer;
a second gate structure wrapping around the third epitaxial layer and the fourth epitaxial layer; and
a third source/drain epitaxial structure and a fourth source/drain epitaxial structure connected to one of the third epitaxial layer and the fourth epitaxial layer but spaced apart from another one of the third epitaxial layer and the fourth epitaxial layer.

9. The device of claim 8, wherein the first epitaxial layer is substantially level with the third epitaxial layer, and the second epitaxial layer is substantially level with the fourth epitaxial layer.

10. The device of claim 8, wherein a size of the first source/drain epitaxial structure is larger than a size of the third source/drain epitaxial structure.

11. The device of claim 8, wherein a top surface of the first source/drain epitaxial structure is higher than a top surface of the third source/drain epitaxial structure.

12. The device of claim 8, wherein a bottom surface of the first source/drain epitaxial structure is lower than a bottom surface of the third source/drain epitaxial structure.

13. The device of claim 8, further comprising:
a first source/drain contact connected to the first source/drain epitaxial structure; and
a second source/drain contact connected to the third source/drain epitaxial structure, wherein the second source/drain contact is deeper than the first source/drain contact.

14. The device of claim 8, wherein a top surface of the third source/drain epitaxial structure is lower than a position of the fourth epitaxial layer.

15. The device of claim 8, wherein a bottom surface of the third source/drain epitaxial structure is higher than a position of the third epitaxial layer.

16. A method comprising:
forming a fin structure over a substrate, wherein the fin structure comprises a first sacrificial layer, a first channel layer, a second sacrificial layer, a second channel layer, a third sacrificial layer, and a third channel layer arranged in a stacking direction, wherein the first channel layer, the second channel layer, and the third channel layer have substantially the same thickness;
forming a dummy gate structure across the fin structure;
forming gate spacers on opposite sides of the dummy gate structure;
recessing the fin structure by using the dummy gate structure and the gate spacers to be a mask to form a recess in the fin structure;
forming liners in the recess and on sidewalls of the fin structure, wherein the liners cover the second channel layer, and the third channel layer but expose the first channel layer;
forming first source/drain epitaxial layers on opposite sides of the first channel layer and spaced apart from the second channel layer and the third channel layer;
removing the liners;
forming second source/drain epitaxial layers on opposite sides of the third channel layer and spaced apart from the first channel layer and the second channel layer; and
replacing the dummy gate structure, the first sacrificial layer, the second sacrificial layer, and the third sacrificial layer with a metal gate structure.

17. The method of claim 16, wherein forming the liner comprising:
depositing a dummy material in the recess;
etching back the dummy material, such that the dummy material covers the first channel layer and exposes the second channel layer and the third channel layer;
forming the liners on the sidewalls of the fin structure and on the dummy material; and
removing the dummy material to expose the first channel layer.

18. The method of claim 16, further comprising:
etching back the second source/drain epitaxial layers.

19. The method of claim 16, further comprising:
after forming the first source/drain epitaxial layers, depositing an interlayer dielectric layer (ILD) over the first source/drain epitaxial layers and in the recess; and
etching back the ILD to expose the third channel layer, wherein the ILD still covers the second channel layer.

20. The method of claim 16, wherein the metal gate structure is in contact with a top surface and a bottom surface of the second channel layer.
